(19) United States
(12) Patent Application Publication
(10) Pub. No.: US 2026/0076004 A1
(43) Pub. Date: Mar. 12, 2026

(54) LED CHIP CONFIGURATION METHOD

(71) Applicant: Lextar Electronics Corporation, Hsinchu City (TW)

(72) Inventors: Chih-Hao LIN, Hsinchu City (TW); Wei-Yuan MA, Hsinchu City (TW); Jin-Shing TSENG, Hsinchu City (TW); Chun-Xin YE, Hsinchu City (TW)

(21) Appl. No.: 19/324,680

(22) Filed: Sep. 10, 2025

(30) Foreign Application Priority Data
Sep. 12, 2024 (TW) 113134589

(51) Int. Cl. H10H 29/34

(52) U.S. Cl. CPC H10H 29/34

(57) ABSTRACT

An LED chip configuration method is provided, comprising forming a plurality of LED chips from a wafer wherein the plurality of LED chips having the same color and different wavelengths; binning the plurality of LED chips into a first group having a minimum wavelength range, a second group having a first middle wavelength range, and a third group having a maximum wavelength range wherein the minimum wavelength range, the first middle wavelength range, and the maximum wavelength range are not overlapped with each other; providing a substrate; and disposing LED chips from the first group, the second group, and the third group on the substrate; wherein the disposed LED chips from different groups are arranged in a staggered manner.

### CROSS REFERENCE TO RELATED APPLICATIONS

This application claims the benefit of Taiwan Patent Application No. 113134589, filed Sep. 12, 2024, the entirety of which is incorporated by reference herein.

### BACKGROUND

### Field of the Disclosure

The application relates in general to an LED chip configuration method.

### Description of the Related Art

With the development of display technology, light-emitting diode chip (LED) panels have been widely used due to their advantages of low power consumption and long life. However, in actual manufacture and usage, LED panels with a single wavelength often have problems with the color being uneven. Therefore, an LED chip binning configuration and an LED chip configuration method are needed to solve the aforementioned problems.

### BRIEF SUMMARY

To address the deficiencies of conventional products, an embodiment of the disclosure provides an LED chip configuration method. The LED chip configuration method includes forming a plurality of LED chips from a wafer wherein the plurality of LED chips having the same color and different wavelengths; binning the plurality of LED chips into a first group having a minimum wavelength range, a second group having a first middle wavelength range, and a third group having a maximum wavelength range wherein the minimum wavelength range, the first middle wavelength range, and the maximum wavelength range are not overlapped with each other; providing a substrate; and disposing LED chips from the first group, the second group, and the third group on the substrate; wherein the disposed LED chips from different groups are arranged in a staggered manner.

### BRIEF DESCRIPTION OF DRAWINGS

The disclosure can be more fully understood by reading the subsequent detailed description and examples with references made to the accompanying drawings, wherein:

FIG. 1A and FIG. 1B are schematic diagrams of a light-emitting diode display device according to some embodiments of the disclosure;

FIG. 2 to FIG. 4 are schematic diagrams of the relationship between the wavelength range and the quantities of LED chip binning configuration according to some embodiments of the disclosure;

FIG. 5A to FIG. 5C is a schematic diagram of the LED chip binning configuration according to some embodiments of the disclosure;

FIG. 6A is a schematic diagram of the blue COB package according to some embodiments of the disclosure;

FIG. 6B is a schematic diagram of the white COB package according to some embodiments of the disclosure;

FIG. 6C is a schematic diagram of the white COB package according to some embodiments of the disclosure;

FIG. 6D is a schematic diagram of the full surface package according to some embodiments of the disclosure;

FIG. 6E is a schematic diagram of the full surface package according to some embodiments of the disclosure;

FIG. 7A is a schematic diagram of the pixel blocks of the LED chip binning configuration according to some embodiments of the disclosure;

FIG. 7B is a first example of the pixel unit of the LED chip binning configuration according to some embodiments of the disclosure;

FIG. 7C is a second example of the pixel unit of the LED chip binning configuration according to some embodiments of the disclosure;

FIG. 7D is a third example of the pixel units of the LED chip binning configuration according to some embodiments of the disclosure;

FIG. 7E is a fourth example of the pixel units of the LED chip binning configuration according to some embodiments of the disclosure; and

FIG. 8 and FIG. 9 are the LED chip configuration method according to some embodiments of the disclosure.

### DETAILED DESCRIPTION OF DISCLOSURE

The present disclosure may be more clearly understood by referring to the following description and the appended drawings. It should be noted that, for the sake of the simplicity of the drawings and comprehensibility for readers, only a portion of the light-emitting unit is illustrated in multiple figures in the present disclosure, and the specific components in the figures are not drawn to scale. In addition, the number and size of each component in the drawings merely serve as an example, and are not intended to limit the scope of the present disclosure. Furthermore, similar and/or corresponding numerals may be used in different embodiments for describing some embodiments simply and clearly, but they do not represent any relationship between different embodiments and/or structures discussed below.

Certain terms may be used throughout the present disclosure and the appended claims to refer to particular elements. Those skilled in the art will understand that electronic device manufacturers may refer to the same components by different names. The present specification is not intended to distinguish between components that have the same function but different names. In the following specification and claims, the words “including”, “comprising”, “having” and the like are open-ended words, so they should be interpreted as meaning “including but not limited to . . . ”. Therefore, when the terms “including”, “comprising”, and/or “having” are used in the description of the disclosure, the presence of corresponding features, regions, steps, operations and/or components is specified without excluding the presence of one or more other features, regions, steps, operations and/or components.

When a corresponding component (i.e. a film layer or region) is referred to as “on another component”, it may be directly on another component, or there may be other components in between. On the other hand, when a component is referred “directly on another component”, there is no component between the former two. In addition, when a component is referred “on another component”, the two components have an up-down relationship in the top view, and this component can be above or below the other component, and this up-down relationship depends on the orientation of the device.

The terms “about,” “equal to,” “equivalent,” “the same as,” “essentially,” or “substantially” are generally interpreted as within 20% of a given value or range, or as interpreted as within 10%, 5%, 3%, 2%, 1%, or 0.5% of a given value or range.

It should be understood that, although the terms “first”, “second” etc. may be used herein to describe various elements, layers and/or portions, and these elements, layers, and/or portions should not be limited by these terms. These terms are only used to distinguish one element, layer, or portion. Thus, a first element, layer or portion discussed below could be termed a second element, layer or portion without departing from the teachings of some embodiments of the present disclosure. In addition, for the sake of brevity, terms such as “first” and “second” may not be used in the description to distinguish different elements. As long as it does not depart from the scope defined by the appended claims, the first element and/or the second element described in the appended claims can be interpreted as any element that meets the description in the specification.

It should be noted that the technical solutions provided by different embodiments below may be interchangeable, combined or mixed to form another embodiment without departing from the spirit of the present disclosure.

Although the present disclosure describes the processes, the methods, the operations, and the steps in a specific order, however, the processes, the methods, the operations, and the steps are not limited to the order described herein. That is, the processes, the methods, the operations, and the steps of the present disclosure can be accomplished in any order to achieve the advantages of the disclosure. Moreover, the specific process, method, operation, or step can be repeated or omitted to achieve the advantages of the disclosure. A person skilled in the art should note that changes, repetitions, or omissions of the processes, the methods, the operations, or the steps of the disclosure will still fall within the scope of the disclosure.

Due to the manufacturing conditions and the environmental factors, the LED chips manufactured from a wafer do not always have the same constant peak wavelength. For example, multiple LED chips formed on the same wafer may have different optoelectronic characteristics, so that it needs to bin the LED chips according to the different optoelectronic characteristics. Therefore, in the present disclosure, the LED chips on the LED wafer are binned (it can be also called classified or grouped) according to the different wavelength ranges, the different wavelength intervals, and different ratios of the number of LED chips, and the LED chips in different binning levels (i.e. in different groups) are mixed and arranged in the device containing the LED chips. Therefore, the utilization rate of the LED chips on the LED wafer can be improved, and the light color of this device with the LED chips can be more uniform.

As to the binning of the LED chips, one of the features in the embodiments of the present disclosure is in that the LED chips with the same luminous color are binned according to the wavelength interval, and the relationship between the wavelength range and the quantities of LED chips is in a Gaussian distribution or in a skewed distribution. Moreover, the number of LED chips binned in the group having the minimum light-emitting wavelength range or the number of LED chips binned in the group having the maximum light-emitting wavelength range is less than or equal to 30% of the total number of LED chips.

In some embodiments, at least 90% of the LED chips on one wafer are used, and less than 10% of the LED chips are not used.

In some embodiments, the skewed distribution is a positively skewed distribution or a negatively skewed distribution.

In some embodiments, the total wavelength range is from 4 nm to 12 nm, such as 4 nm, 5 nm, 6 nm, 7 nm, 8 nm, 9 nm, 10 nm, 11 nm, 12 nm, or the value between the aforementioned values or ranges. However, the present disclosure is not limited thereto.

In some embodiments, the interval of the minimum light-emitting wavelength range and the interval of the maximum light-emitting wavelength range are each less than or equal to 25% of the total wavelength range.

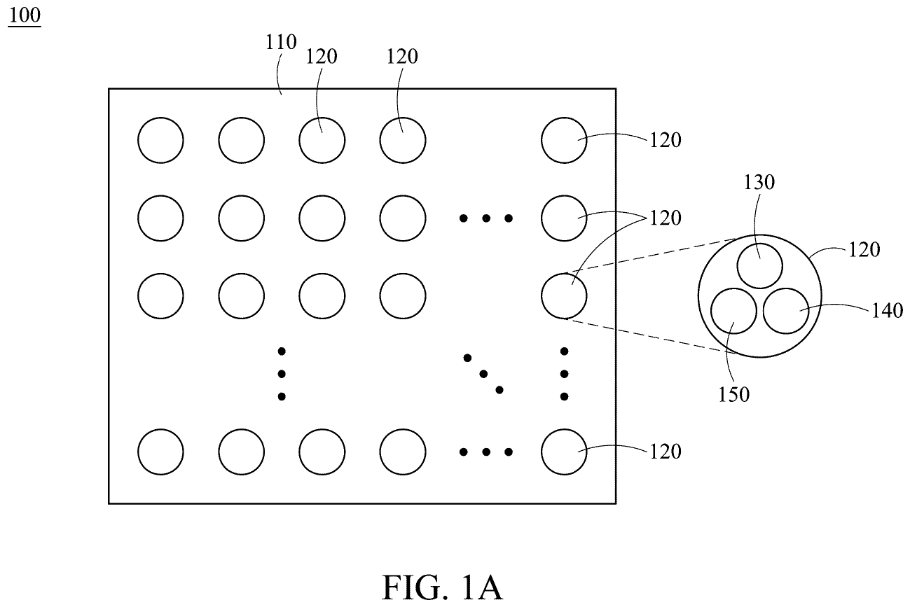

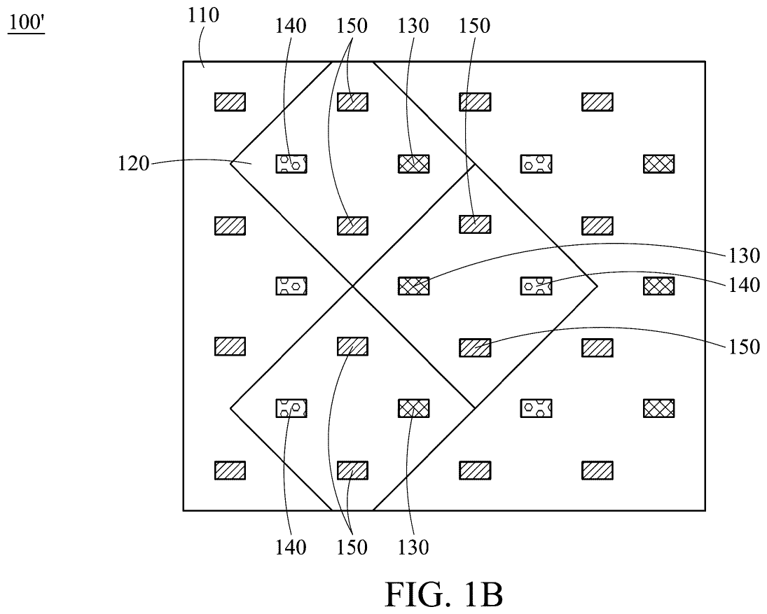

Referring to FIG. 1A and FIG. 1B, FIG. 1A and FIG. 1B show light-emitting diode display devices 100 and 100′ according to some embodiments of the present disclosure. Each of the light-emitting diode display devices 100 and 100′ includes a substrate 110, and a plurality of pixel units 120 are disposed on the substrate 110.

As shown in the enlarged diagram of one of the pixel units 120 in FIG. 1A, each pixel unit 120 at least includes sub-pixel units of three colors R, G, and B. Each sub-pixel unit has at least one light-emitting diode chip (hereinafter referred to as the LED chip) corresponding to the color of the sub-pixel unit. In other words, each pixel unit 120 includes a red light-emitting diode chip (hereinafter referred to as the red LED chip) 130, a blue light-emitting diode chip (hereinafter referred to as the blue LED chip) 140, and a green light-emitting diode chip (hereinafter referred to as the green LED chip) 150.

In some embodiments, as shown in FIG. 1B, in each of the pixel units 120 of the light-emitting diode display device 100′, the red LED chip 130, the blue LED chip 140, and the green LED chip 150 can be arranged in an irregular manner, but the present disclosure is not limited thereto. Moreover, due to the characteristic that the human eye is more sensitive to the green wavelength band, a greater number of green chips may be provided in the display to improve the image resolution and image quality of the display. As shown in FIG. 1B, each pixel unit 120 includes two green LED chips 150, but the present disclosure is not limited thereto.

In FIG. 1A and FIG. 1B, the red LED chip 130, the blue LED chip 140, and the green LED chip 150 are respectively arranged in the light-emitting diode display devices 100 and 100′ through a binning and mixing process. In the light-emitting diode display devices in the embodiments of the disclosure, the color difference at the interface between spliced modules can be eliminated by binning the LED chips at a wavelength interval and controlling the relationship between the wavelength range and the quantities of LED chips.

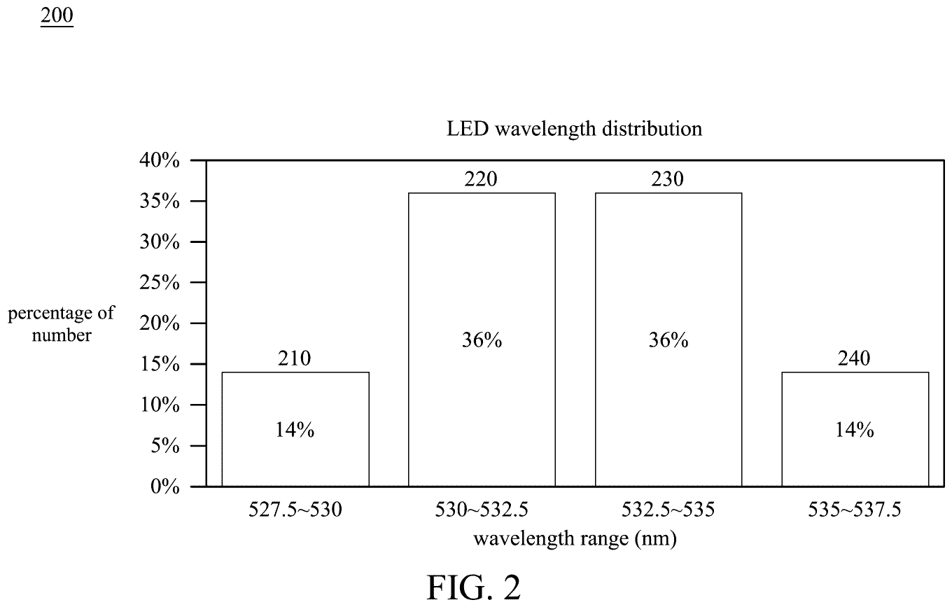

The binning process of the LED chips can refer to FIG. 2. FIG. 2 is a schematic diagram of the relationship between the wavelength range and the quantities of LED chip binning configuration 200 according to some embodiments of the disclosure. FIG. 2 illustrates the LED chips with a single color as an example, such as the green LED chips. It should be noted that, the binning configuration described in the present disclosure can applied to the LED chips with other color (such as the red LED chips, the blue LED chips, or etc.), unless expressly described otherwise.

The LED chip binning configuration 200 includes a plurality LED chips. These LED chips have different light-emitting wavelength but have the same light-emitting color, and these LED chips can be classified into a plurality of groups according to the wavelength interval.

As shown in FIG. 2, the LED chip binning configuration 200 is binned into four groups that includes a first LED chip group 210, a second LED chip group 220, a third LED chip group 230, and a fourth LED chip group 240. The first LED chip group 210 is a group having the minimum light-emitting wavelength range in the LED chip binning configuration 200, and the fourth LED chip group 240 is a group having the maximum light-emitting wavelength range in the LED chip binning configuration 200.

FIG. 2 exemplifies the binning process for the green LED chips from a green LED wafer. The wavelength range of the green LED chip binning configuration 200 is from 527.5 nm to 537.5 nm, so that the total wavelength range is 10 nm. The wavelength range of the first LED chip group 210 is in a range of 527.5 nm to 530 nm, and the wavelength interval of the first LED chip group 210 is 2.5 nm. The wavelength range of the second LED chip group 220 is in a range of 530 nm to 532.5 nm, and the wavelength interval of the second LED chip group 220 is 2.5 nm. The wavelength range of the third LED chip group 230 is in a range of 532.5 nm to 535 nm, and the wavelength interval of the third LED chip group 230 is 2.5 nm. The wavelength range of the fourth LED chip group 240 is in a range of 535 nm to 537.5 nm, and the wavelength interval of the fourth LED chip group 240 is 2.5 nm. Although the wavelength ranges of the LED chips in each group are different, the wavelength intervals of the LED chips in each group are the same (all of the wavelength intervals are 2.5 nm).

As shown in FIG. 2, the relationship between the wavelength range and the quantities of LED chips in the LED chip binning configuration 200 is in a Gaussian distribution, wherein the number of LED chips binned in the group having the minimum light-emitting wavelength range (the first LED chip group 210) or the number of LED chips binned in the group having the maximum light-emitting wavelength range (the fourth LED chip group 240) is less than or equal to 30% of the total number of LED chips in the LED chip binning configuration 200.

As shown in FIG. 2, the number of LED chips in the first LED chip group 210 is 14% of the total number of LED chips in the LED chip binning configuration 200, the number of LED chips in the second LED chip group 220 is 36% of the total number of LED chips in the LED chip binning configuration 200, the number of LED chips in the third LED chip group 230 is 36% of the total number of LED chips in the LED chip binning configuration 200, and the number of LED chips in the fourth LED chip group 240 is 14% of the total number of LED chips in the LED chip binning configuration 200.

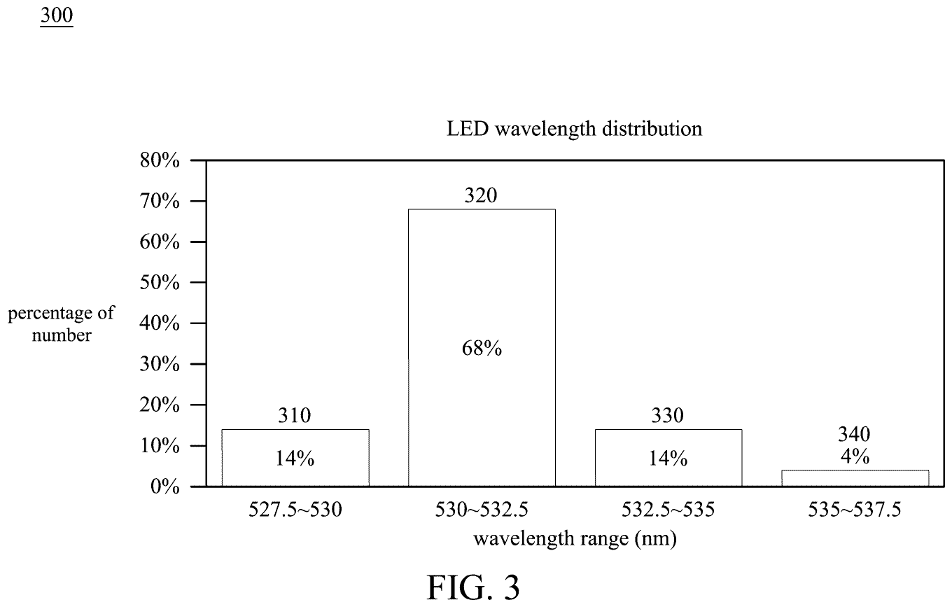

Referring to FIG. 3, FIG. 3 is a schematic diagram of the relationship between the wavelength range and the quantities of LED chip binning configuration 300 according to some embodiments of the disclosure. The LED chip binning configuration 300 in FIG. 3 is similar to the LED chip binning configuration 200 in FIG. 2, so that the descriptions of similar content are not repeated in the interest of brevity.

The relationship between the wavelength range and the quantities of LED chips in the LED chip binning configuration 300 is in a skewed distribution. As shown in FIG. 3, the relationship between the wavelength range and the quantities of LED chips is in a positively skewed distribution. The number of LED chips in the first LED chip group 310 is 14% of the total number of LED chips in the LED chip binning configuration 300, the number of LED chips in the second LED chip group 320 is 68% of the total number of LED chips in the LED chip binning configuration 300, the number of LED chips in the third LED chip group 330 is 14% of the total number of LED chips in the LED chip binning configuration 300, and the number of LED chips in the fourth LED chip group 340 is 4% of the total number of LED chips in the LED chip binning configuration 300.

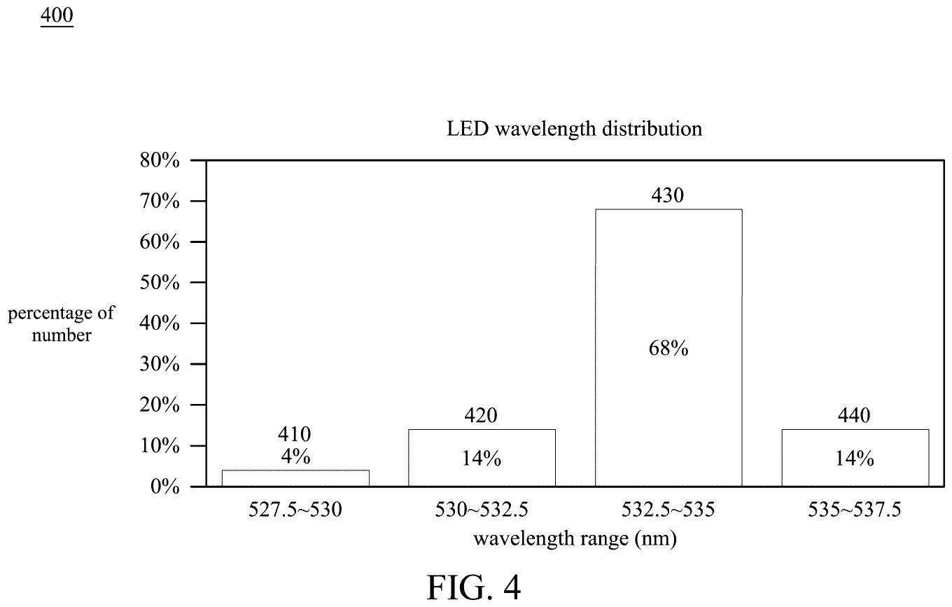

Referring to FIG. 4, FIG. 4 is a schematic diagram of the relationship between the wavelength range and the quantities of LED chips in the LED chip binning configuration 400 according to some embodiments of the disclosure. The LED chip binning configuration 400 in FIG. 4 is similar to the LED chip binning configuration 200 in FIG. 2, so that the descriptions of similar parts are not repeated in the interest of brevity.

The relationship between the wavelength range and the quantities of LED chips in the LED chip binning configuration 400 is in a skewed distribution. As shown in FIG. 4, the relationship between the wavelength range and the quantities of LED chips is in a negatively skewed distribution. The number of LED chips in the first LED chip group 410 is 4% of the total number of LED chips in the LED chip binning configuration 400, the number of LED chips in the second LED chip group 420 is 14% of the total number of LED chips in the LED chip binning configuration 400, the number of LED chips in the third LED chip group 430 is 68% of the total number of LED chips in the LED chip binning configuration 400, and the number of LED chips in the fourth LED chip group 440 is 14% of the total number of LED chips in the LED chip binning configuration 400.

Similarly, the red LED chips from a red LED wafer and the blue LED chips from a blue LED wafer can be also binned through the aforementioned configuration. For example, the wavelength range of the red LED chips is in a range of 620 nm to 630 nm. The red LED chips can be binned into four groups, and the wavelength intervals of the four groups are the same (all of the wavelength intervals are 2.5 nm). The relationship between the wavelength range and the quantities of red LED chips is in a Gaussian distribution or in a skewed distribution. The number of LED chips binned in the group having the minimum light-emitting wavelength range or the number of LED chips binned in the group having the maximum light-emitting wavelength range is less than or equal to 30% of the total number of LED chips. For example, the wavelength range of the blue LED chips is in a range of 465 nm to 475 nm. The blue LED chips can be binned into four groups, and the wavelength intervals of each group are the same (all of the wavelength intervals are 2.5 nm). The relationship between the wavelength range and the quantities of blue LED chips is in a Gaussian distribution or in a skewed distribution. The number of LED chips in the group having the minimum light-emitting wavelength range or the number of LED chips in the group having the maximum light-emitting wavelength range is less than or equal to 30% of the total number of LED chips.

For increasing the utilization rate of the LED chips on the LED wafer, the binned LED chips are subsequently mixed and arranged in the device containing the LED chips, so as to achieve that at least 90% of the LED chips on this wafer are used. The following is an embodiment of the red LED chips, the green LED chips, and the blue LED chips mixed and arranged on the pixel of the LED display device, but the present disclosure is not limited thereto.

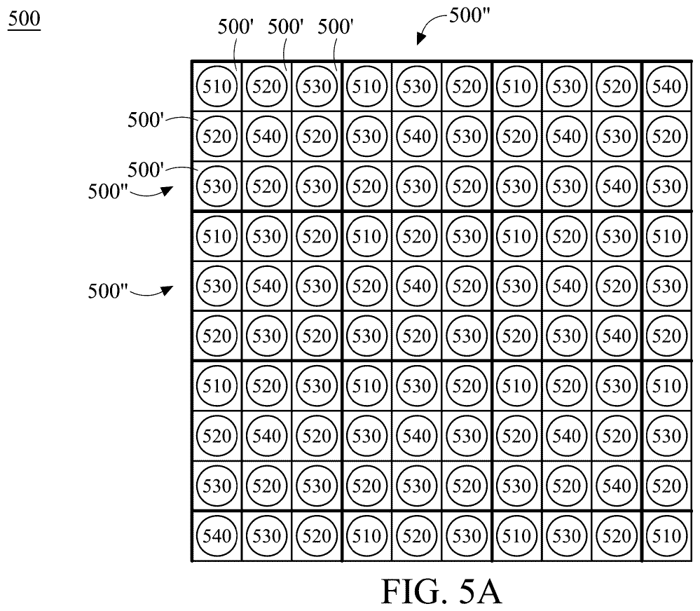

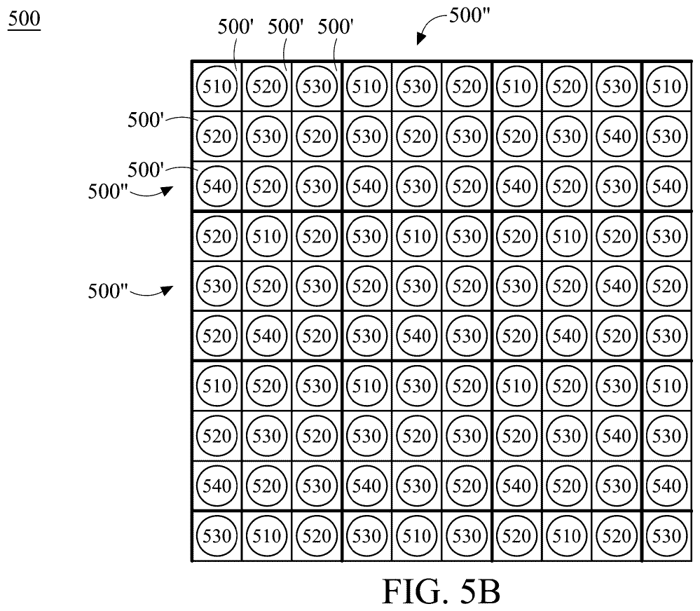

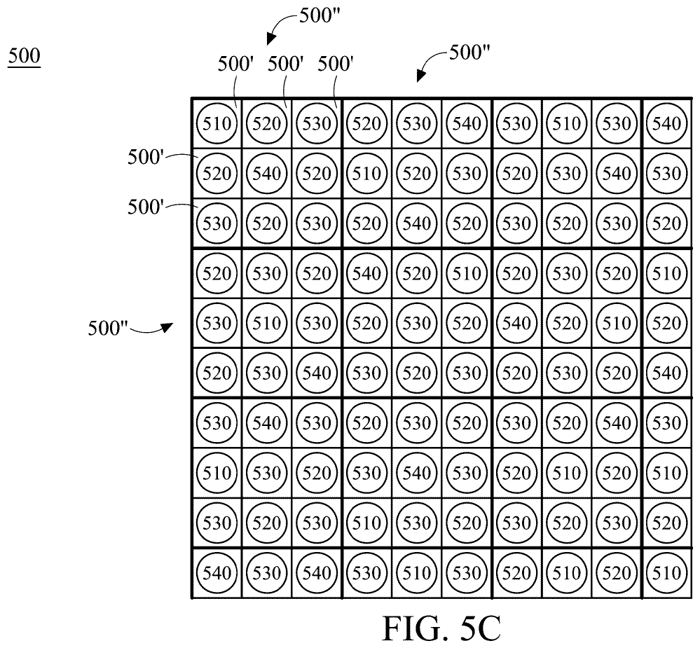

Referring to FIG. 5A to FIG. 5C, which are schematic diagrams of an LED chip binning configuration 500 according to some embodiments of the disclosure. The relationship between the wavelength range and the quantities of LED chip binning configuration 500 in FIG. 5A to FIG. 5C is similar to that of LED chip binning configuration 200 in FIG. 2, so that the descriptions of similar content are not repeated in the interest of brevity.

For ease of understanding, in FIG. 5A to FIG. 5C, the pixel units 500′ of the LED binning configuration 500 (representing by thin lines) are assembled into pixel blocks 500″ (representing by thick lines). Each of the pixel blocks 500″ can include a 3×3 pixel matrix, i.e. nine pixel units 500′. Each pixel unit 500′ includes at least one red LED chip, at least one green LED chip, and at least one blue LED chip.

Taking the red LED chips as an example, the red LED chips from a red LED wafer can be binned into four groups through the binning method illustrated in FIG. 2: a group having the minimum light-emitting wavelength range (a first LED chip group 510), groups with the middle light-emitting wavelength ranges (a second LED chip group 520 and a third LED chip group 530), and a group having the maximum light-emitting wavelength range (a fourth LED chip group 540). Subsequently, the binned red LED chips are mixed and arranged in the pixel blocks 500″. As shown in FIG. 5A to FIG. 5C, in order to make the binning arrangement of the red LED chips in the pixel blocks 500″ more uniform, the red LED chips from the different groups are arranged in a staggered manner, and the red LED chips from the same group are not adjacent to each other. Moreover, the group having the minimum light-emitting wavelength range (the first LED chip group 510) and the group having the maximum light-emitting wavelength range (the fourth LED chip group 540) are not adjacent to each other. Since the wavelength ranges of the LED chips binned in the groups having the middle light-emitting wavelength ranges (the second LED chip group 520 and the third LED chip group 530) are not significantly different, one of the groups having a first middle light-emitting wavelength range can be adjacent to another group having a second middle light-emitting wavelength range. Similarly, the green LED chips from a green LED wafer and the blue LED chips from the blue LED wafer can be binned using the same aforementioned method as for the red LED chips. That is, they can be binned into a group having the minimum light-emitting wavelength range, two groups having the middle light-emitting wavelength ranges, and a group having the maximum light-emitting wavelength range. After that, the binned green LED chips and the binned blue LED chips can be mixed and arranged by the same configuration shown in FIG. 5A to FIG. 5C, so as to be uniformly arranged in the pixel blocks 500″. Accordingly, the color of light of the LED display device can become more uniform.

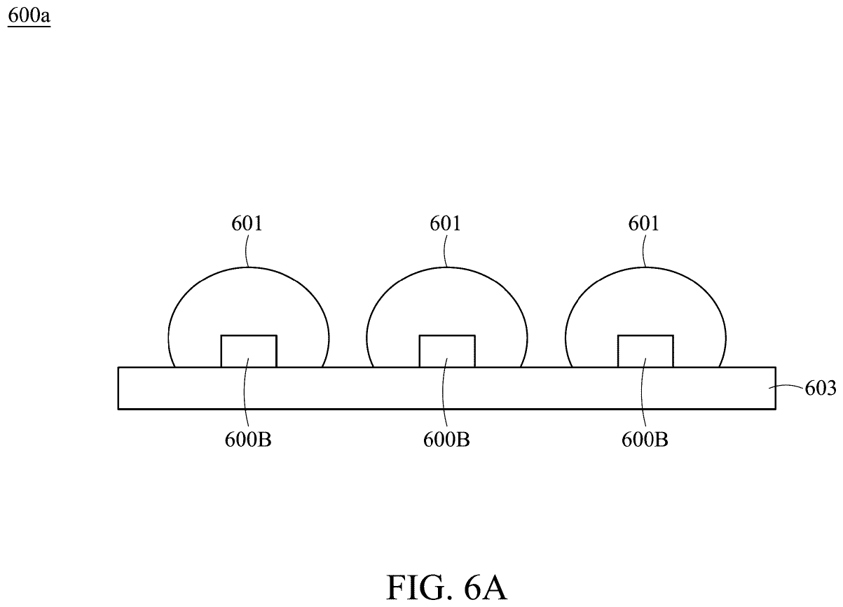

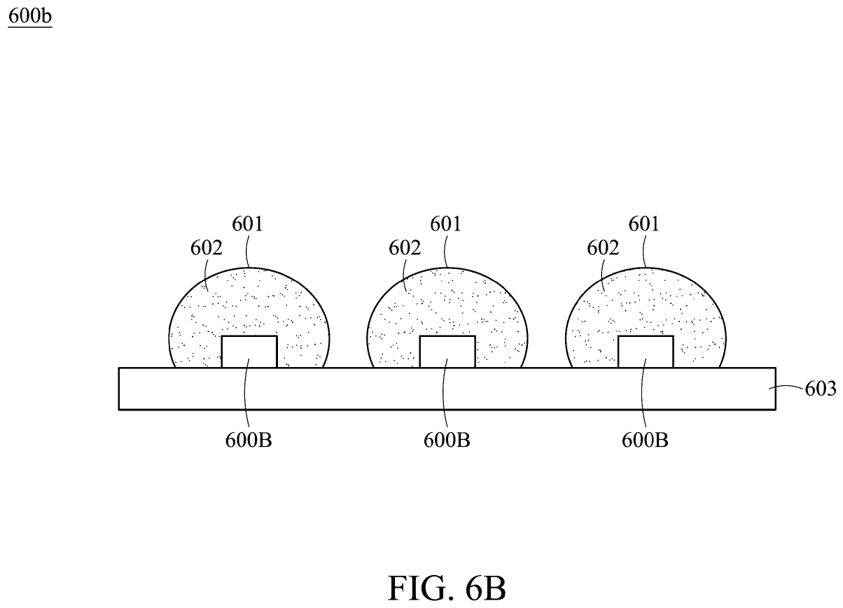

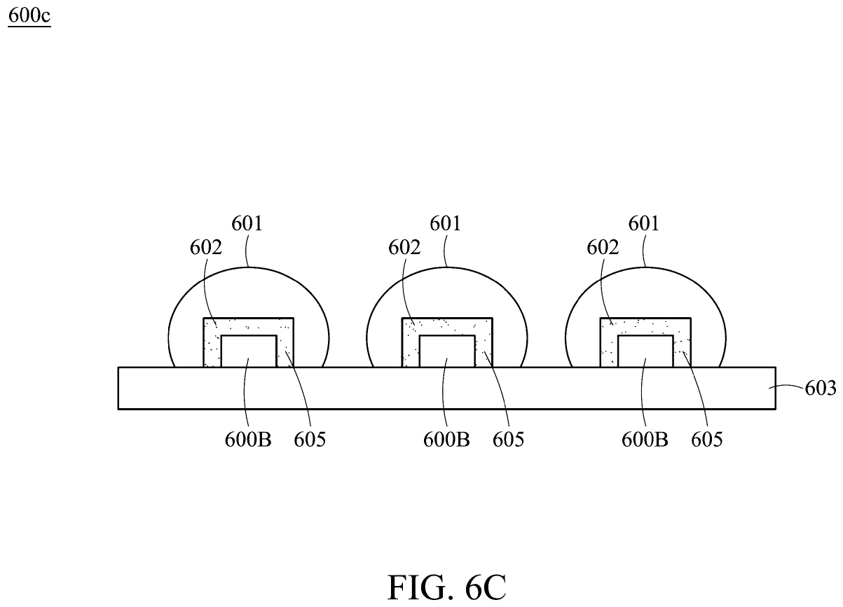

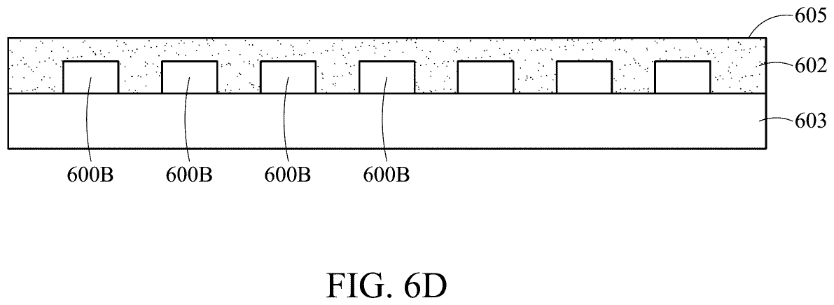

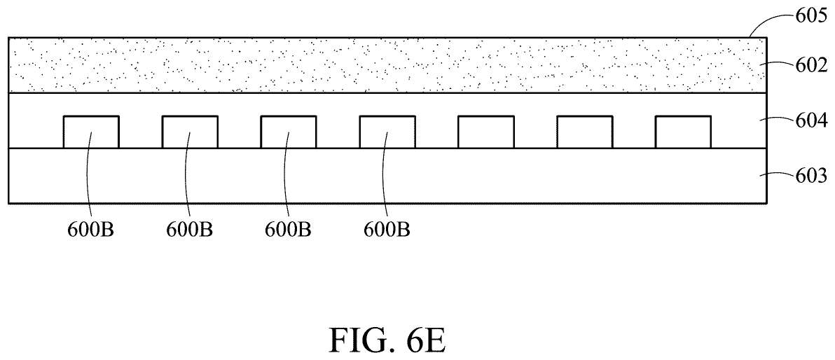

Moreover, the LED chip binning configuration of the present disclosure can be also applied on the display or the LED backlight device of the automotive dashboard. Take the blue LED chips that are usually used in the LED backlight device as an example: The blue LED chips can be binned according to any of the embodiments shown in FIG. 2 to FIG. 4, and can be mixed and arranged on the substrate by the arrangement configuration of any of the embodiments shown in FIG. 5A to FIG. 5C. Therefore, the blue LED chips with different binned groups can be used in the LED backlight module at the same time to reduce the cost and to provide the uniform backlight. FIG. 6A to FIG. 6E disclose the embodiments of different LED backlight devices, but the present disclosure is not limited thereto, showing different package structures packaging the blue LED chips as required.

FIG. 6A is a backlight device 600a according to some embodiments of the disclosure. The backlight device 600a includes a substrate 603 and a plurality of blue LED chips 600B disposed on the substrate 603. Each of the blue LED chips 600B is packaged by a transparent encapsulant 601. In FIG. 6A, the blue LED chips 600B are directly mounted and packaged on the substrate 603 in a COB (Chip on Board) package manner. In FIG. 6A, the blue LED chips 600B are binned according to any of the embodiments shown in FIG. 2 to FIG. 4, and are mixed and arranged on the substrate 603 by the arrangement configuration of any of the embodiments shown in FIG. 5A to FIG. 5C, so that the backlight module can display the uniform blue light. In some embodiments, the substrate 603 is a substrate with conductive function, such as a substrate having a conductive structure. In some embodiments, the material of the substrate 603 includes glass, quartz, sapphire, ceramics (such as aluminum oxide (Al₂O₃)), BT (bismaleimide triazine) resin, glass epoxy resin (such as FR-4), epoxy molding compound (EMC), other suitable material, or a combination thereof, but the present disclosure is not limited thereto. In some embodiments, the substrate 603 includes light-transmissive material, translucent material, or opaque material, but the present disclosure is not limited thereto.

Referring to FIG. 6B, FIG. 6B is a schematic diagram of a backlight device 600b according to some embodiments of the disclosure. The backlight device 600b is similar to the backlight device 600a, and the difference is in that the transparent encapsulant 601 of the backlight device 600b further includes a wavelength conversion material 602. For example, the wavelength conversion material 602 may be quantum dots, phosphor, or a mixture thereof. Take the backlight device 600b emitting the white light as an example: The wavelength conversion material 602 may be the yellow wavelength conversion material or a combination of the green wavelength conversion material and the red wavelength conversion material. In some embodiments, the material of the transparent encapsulant 601 can be an acrylic resin, an organosiloxane resin, an acrylate modified polyurethane resin, an acrylate modified silicone resin, or an epoxy resin. Moreover, since the blue LED chips are binned and arranged on the substrate 603 according to the present disclosure, the backlight device 600b can provide uniform white light.

Referring to FIG. 6C, FIG. 6C is a schematic diagram of a backlight device 600c according to some embodiments of the disclosure. The backlight device 600c includes a substrate 603, and a plurality of blue LED chips 600B disposed on the substrate 603. A wavelength conversion layer 605 conformally conforms to the shape of each blue LED chip 600B and encloses its tops surface and lateral surface for emitting the white light, and a transparent encapsulant 601 encloses each blue LED chips 600B and the wavelength conversion layer 605. In FIG. 6C, the blue LED chips 600B are binned according to any of the embodiments shown in FIG. 2 to FIG. 4 and are mixed and arranged on the substrate 603 by the arrangement configuration of any of the embodiments shown in FIG. 5A to FIG. 5C, and the wavelength conversion layer 605 can further correspond to let the backlight device 600c providing the uniform white light. In some embodiments, the wavelength conversion layer 605 includes the wavelength conversion material 602, wherein the wavelength conversion material 602 may include the yellow wavelength conversion material or the combination of the green wavelength conversion material and the red wavelength conversion material.

Referring to FIG. 6D, FIG. 6D is a schematic diagram of a backlight device 600d according to some embodiments of the disclosure. The backlight device 600d includes a substrate 603, a plurality of blue LED chips 600B disposed on the substrate 603, and a wavelength conversion layer 605 disposed on the substrate 603 and enclosing multiple blue LED chips 600B to emit white light. In FIG. 6D, the blue LED chips 600B are binned according to any of the embodiments shown in FIG. 2 to FIG. 4 and are mixed and arranged on the substrate 603 by the arrangement configuration of any of the embodiments shown in FIG. 5A to FIG. 5C, and the wavelength conversion layer 605 can further correspond to let the backlight device 600d providing the uniform white light. In some embodiments, the wavelength conversion layer 605 includes the wavelength conversion material 602, wherein the wavelength conversion material 602 may include the yellow wavelength conversion material or the combination of the green wavelength conversion material and the red wavelength conversion material.

Referring to FIG. 6E, FIG. 6E is a schematic diagram of a backlight device 600e according to some embodiments of the disclosure. The backlight device 600e includes a substrate 603, a plurality of blue LED chips 600B disposed on the substrate 603, a transparent layer 604 disposed on the substrate and enclosing multiple blue LED chips 600B, and a wavelength conversion layer 605 disposed on the transparent layer 604. In FIG. 6E, the blue LED chips 600B are binned according to any of the embodiments shown in FIG. 2 to FIG. 4 and are mixed and arranged on the substrate 603 by the arrangement configuration of any of the embodiments shown in FIG. 5A to FIG. 5C, and the wavelength conversion layer 605 can further correspond to let the backlight device 600e providing the uniform white light. In some embodiments, the wavelength conversion layer 605 includes the wavelength conversion material 602, wherein the wavelength conversion material 602 may include the yellow wavelength conversion material or the combination of the green wavelength conversion material and the red wavelength conversion material.

Since the blue LED chips are binned and mixed and arranged on the substrate 603 according to the present disclosure, the wavelength conversion layer 605 can further correspond to let the backlight devices 600b-600e providing the uniform white light.

In some embodiments, the yellow wavelength conversion material may be yellow phosphor, such as YAG phosphor, TAG phosphor, or etc.

In some embodiments, the green wavelength conversion material may include green quantum dots, green phosphor, or the combination thereof. In some embodiments, the green quantum dots may be CdSe quantum dots, CdS quantum dots, CdTe quantum dots, InP quantum dots, InN quantum dots, AlInN quantum dots, InGaN quantum dots, AlGaInN quantum dots, CuInGaSe quantum dots, and green all-inorganic perovskite quantum dots with the chemical formula CsPb(Br₁₋ₐIₐ)₃ in which 0≤a<0.5, but the present disclosure is not limited thereto. In some embodiments, the green phosphor may be LuAG phosphor, the β-SiAlON phosphor, or the silicate phosphor, but the present disclosure is not limited thereto.

In some embodiments, the red wavelength conversion material may include red quantum dots, red phosphor, or the combination thereof. In some embodiments, the red quantum dots may be InP quantum dots, CdSe quantum dots, or red all-inorganic perovskite quantum dots with the chemical formula CsPb(Br_{1-b}I_{b})₃ in which 0.5≤b<1, but the present disclosure is not limited thereto. In some embodiments, the red phosphor can be (Sr,Ca) AlSiN₃:Eu²⁺, Ca₂Si₅N₈:Eu²⁺, Sr(LiAl₃N₄):Eu²⁺, Mn-doped red fluoride phosphor (such as K₂GeF₆:Mn⁴⁺, K₂SiF₆:MN⁴⁺, K₂TiF₆:Mn⁴⁺, or etc.), but the present disclosure is not limited thereto.

In some embodiments, the wavelength conversion material 602 may be the combination of the red phosphor and the green quantum dots, wherein the red phosphor comprises K₂SiF₆:Mn⁴⁺.

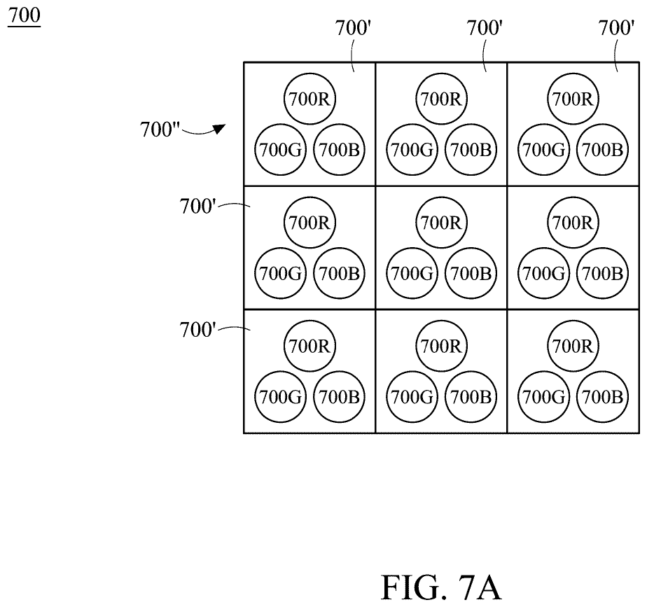

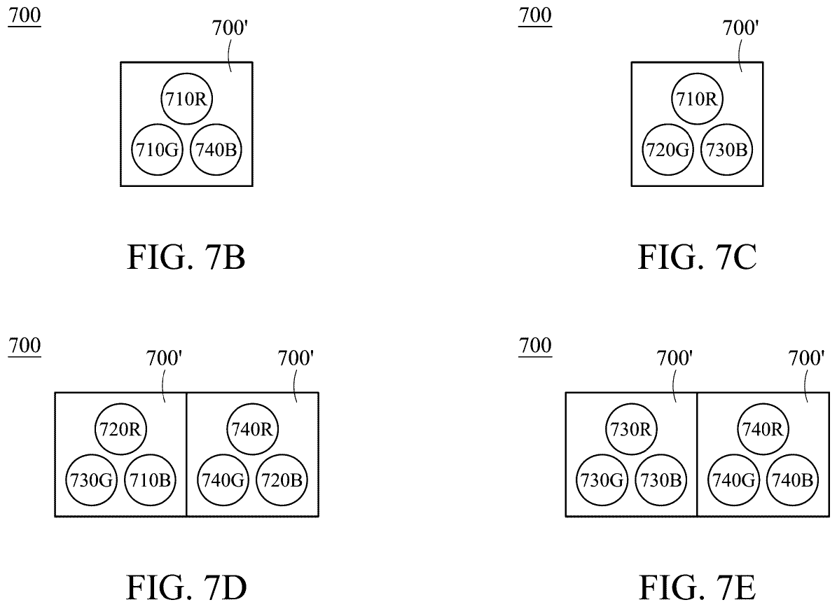

Referring to FIG. 7A, FIG. 7A is a schematic diagram of a pixel block 700″ of an LED chip binning configuration 700 according to some embodiments of the disclosure. Each of the pixel units 700′ in the pixel block 700″ at least includes a red LED chip 700R, a blue LED chip 700B, and a green LED chip 700G.

The red LED chips 700R in the LED chip binning configuration 700 have different light-emitting wavelengths, and are binned according to a red light wavelength interval. The blue LED chips 700B in the LED chip binning configuration 700 have different light-emitting wavelengths, and are binned according to a blue light wavelength interval. The green LED chips 700G in the LED chip binning configuration 700 have different light-emitting wavelengths, and are binned according to a green light wavelength interval.

The relationship between the wavelength range and the quantities of red LED chips 700R, the blue LED chips 700B, and the green LED chips 700G is in a Gaussian distribution or in a skewed distribution, and the number of LED chips binned in the group having the minimum light-emitting wavelength range or binned the group having the maximum light-emitting wavelength range is less than or equal to 30% of the total number of each LED chips. For example, referring to the embodiments shown in FIG. 2 to FIG. 4, each of the red LED chips 700R, the blue LED chips 700B, and the green LED chips 700G can be binned into four groups. That is, the red LED chips 700R can be binned into a first red LED chip group to a fourth red LED chip group, the blue LED chips 700B can be binned into a first blue LED chip group to a fourth blue LED chip group, and the green LED chips 700G can be binned into a first green LED chip group and a fourth green LED chip group.

In order to make the LED chip binning configuration 700 more uniform, the same-color LED chips, i.e. LED chips having the same color, from the different groups are arranged in a staggered manner, so that the same-color LED chips from the same group are not adjacent to each other. Moreover, among the LED chips of the same color, the LED chips binned in the group having the minimum light-emitting wavelength range and the LED chips binned in the group having the maximum light-emitting wavelength range are not adjacent to each other. Since the wavelength ranges of the same-color LED chips binned in the groups having the middle light-emitting wavelength range are not significantly different, the same-color LED chips binned in one of the groups having a first middle light-emitting wavelength range can be adjacent to the same-color LED chips in another group having a second middle light-emitting wavelength range. The detail description of the same-color LED chips can be referred to the embodiments shown in FIG. 5A to FIG. 5C.

When the configuration rules of the same-color LED chips in the previous paragraph are followed, the red LED chip 700R, the green LED chip 700G, and the blue LED chip 700B in each pixel unit 700′ can belong to the same group or the different groups, so that each pixel unit 700′ can include the red LED chip 700R, the green LED chip 700G, and the blue LED chip 700B from any wavelength range group. Moreover, the different-color LED chips from any groups can be adjacent to each other. In other words, the LED chip with one color can be adjacent to the LED chip with another color from any wavelength range group.

Referring to FIG. 7B, FIG. 7B is a first example of the pixel unit 700′ of the LED chip binning configuration 700 according to some embodiments of the disclosure. In the first example of the disclosure, in one pixel unit 700′, the red LED chip 710R from the first red LED chip group, the green LED chip 710G from the first green LED chip group, and the blue LED chip 740B in the fourth blue LED chip group can be disposed therein.

Referring to FIG. 7C, FIG. 7C is a second example of the pixel unit 700′ of the LED chip binning configuration 700 according to some embodiments of the disclosure. In the second example of the disclosure, in one pixel unit 700′, the red LED chip 710R from the first red LED chip group, the green LED chip 720G from the second green LED chip group, and the blue LED chip 730B from the third blue LED chip group can be disposed therein.

It can be seen that, in the first example and the second example, one pixel unit 700′ can include the different-color LED chips from any groups (from the same group or from the different groups). In the first example, the red LED chip 710R from the first red LED chip group and the green LED chip 710G from the first green LED chip group are disposed in the same pixel unit 700′.

Referring to FIG. 7D, FIG. 7D is a third example of the pixel units 700′ of the LED chip binning configuration 700 according to some embodiments of the disclosure. In the third example of the disclosure, in one pixel unit 700′, the red LED chip 720R from the second red LED chip group, the green LED chip 730G from the third green LED chip group, and the blue LED chip 710B from the first blue LED chip group can be disposed therein. Moreover, in the adjacent pixel unit 700′, the red LED chip 740R from the fourth red LED chip group, the green LED chip 740G from the fourth green LED chip group, and the blue LED chip 720B in the second blue LED chip group can be disposed therein.

Referring to FIG. 7E, FIG. 7E is a fourth example of the pixel units 700′ of the LED chip binning configuration 700 according to some embodiments of the disclosure. In the fourth example of the disclosure, in one pixel unit 700′, the red LED chip 730R from the third red LED chip group, the green LED chip 730G from the third green LED chip group, and the blue LED chip 730B from the third blue LED chip group can be disposed therein. Moreover, in the adjacent pixel unit 700′, the red LED chip 740R in the fourth red LED chip group, the green LED chip 740G from the fourth green LED chip group, and the blue LED chip 740B from the fourth blue LED chip group can be disposed therein.

It can be seen that, in the third example and the fourth example, in two adjacent pixel units 700′, the different-color LED chips from any groups can be adjacent to each other (in the third example, the blue LED chip 710B from the first blue LED chip group is adjacent to the red LED chip 740 R from the fourth red LED chip group). However, in two adjacent pixel units 700′, the same-color LED chips should be arranged according to the description in FIG. 5A to FIG. 5C of the disclosure.

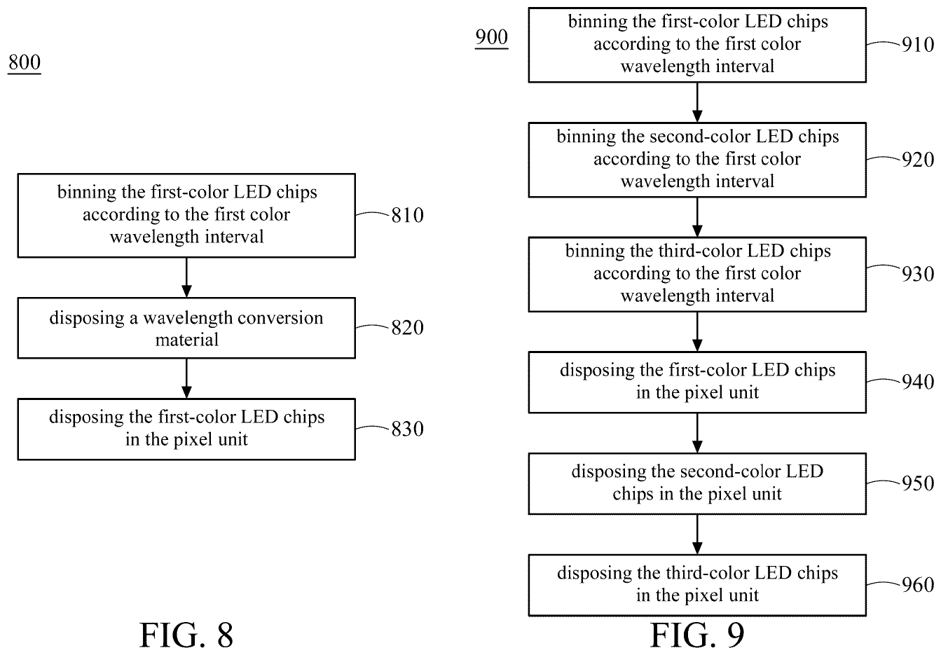

Referring to FIG. 8, FIG. 8 is an LED chip configuration method 800 according to some embodiments of the disclosure.

The LED chip configuration method 800 can be started in the step 810. In the step 810, the first-color LED chips can be binned according to the first color wavelength interval. The step 810 is applied to let the relationship between the first color light-emitting wavelength range and the quantities of first-color LED chips being in a Gaussian distribution or in a skewed distribution. The relationship between the wavelength range and the quantities of first-color LED chips can refer to the embodiments in FIG. 2 to FIG. 4. The first color is blue according to some embodiments of the disclosure.

In the step 820, a wavelength conversion material is disposed. The step 820 is applied to form a white backlight. The detail description of the wavelength conversion material can refer to the embodiments in FIG. 6B to FIG. 6E of the disclosure.

In the step 830, the first-color LED chips are disposed in the pixel unit. The step 830 is applied to staggered arrange the first-color LED chips from the different groups. The configuration of the first-color LED chips can refer to the embodiments in FIG. 5A to FIG. 5C and FIG. 7B to FIG. 7C.

Referring to FIG. 9, FIG. 9 is an LED chip configuration method 900 according to some embodiments of the disclosure.

The LED chip configuration method 900 can be started in the step 910. In the step 910, the first-color LED chips can be binned according to the first color wavelength interval. The step 910 is applied to let the relationship between the first color light-emitting wavelength range and the quantities of first-color LED chips being in a Gaussian distribution. The relationship between the wavelength range and the quantities of first-color LED chips can refer to the embodiments in FIG. 2 to FIG. 4. The first color is one of red, green and blue.

In the step 920, the second-color LED chips can be binned according to the second color wavelength interval. The step 920 is applied to let the relationship between the second color light-emitting wavelength range and the quantities of second-color LED chips being in a Gaussian distribution or in a skewed distribution. The relationship between the wavelength range and the quantities of second-color LED chips can refer to the embodiments in FIG. 2 to FIG. 4. According to some embodiments, the second color is another one of red, green and blue relative to the first color.

In the step 930, the third-color LED chips can be binned according to the third color wavelength interval. The step 930 is applied to let the relationship between the third color light-emitting wavelength range and the quantities of third-color LED chips being in a Gaussian distribution or in a skewed distribution. The relationship between the wavelength range and the quantities of third-color LED chips can refer to the embodiments in FIG. 2 to FIG. 4. According to some embodiments, the third color is another one of red, green and blue relative to the first color and the second color.

In the step 940, the first-color LED chips are disposed in the pixel units. The step 940 is applied to let each pixel unit including at least one first-color LED chip. The step 940 is applied to staggered arrange the first-color LED chips from the different groups, and the first-color LED chips from the same group are not adjacent to each other. Moreover, the first-color LED chips binned in the group having the minimum light-emitting wavelength range and the first-color LED chips binned in the group having the maximum light-emitting wavelength range are not adjacent to each other. The first-color LED chips binned in one of the groups having a first middle light-emitting wavelength range can be adjacent to the first-color LED chips binned in another group having a second middle light-emitting wavelength range. The detail description of the first-color LED chips can refer to the embodiments in FIG. 5A to FIG. 5C and the embodiments in FIG. 7B to FIG. 7C.

In the step 950, the second-color LED chips are disposed in the pixel units. The step 950 is applied to let each pixel unit including at least one second-color LED chip. The step 950 is applied to staggered arrange the second-color LED chips from the different groups, and the second-color LED chips from the same group are not adjacent to each other. Moreover, the second-color LED chips in the group having the minimum light-emitting wavelength range and the second-color LED chips in the group having the maximum light-emitting wavelength range are not adjacent to each other. The second-color LED chips in one of the groups with a first middle light-emitting wavelength range can be adjacent to the second-color LED chips in another group with a second middle light-emitting wavelength range. The detail description of the second-color LED chips can refer to the embodiments in FIG. 5A to FIG. 5C and the embodiments in FIG. 7B to FIG. 7C.

It should be noted that, when the configuration rules of the same-color LED chips are followed, the first-color LED chip in any group and the second-color LED chip in any group can be disposed in each pixel unit, and the first-color LED chip in any group and the second-color LED chip in any group can be adjacent to each other. The relationship of the configuration of the first-color LED chip and the second-color LED chip can refer to the embodiments in FIG. 7A and FIG. 7D to FIG. 7E.

In the step 960, the third-color LED chips are disposed in the pixel units. The step 960 is applied to let each pixel unit including at least one third-color LED chip. The step 960 is applied to staggered arrange the third-color LED chips from the different groups, and the third-color LED chips from the same group are not adjacent to each other. Moreover, the third-color LED chips binned in the group having the minimum light-emitting wavelength range and the third-color LED chips binned in the group having the maximum light-emitting wavelength range are not adjacent to each other. The third-color LED chips binned in one of the groups having a first middle light-emitting wavelength range can be adjacent to the third-color LED chips binned in another group having a second middle light-emitting wavelength range. The detail description of the third-color LED chips can refer to the embodiments in FIG. 5A to FIG. 5C and the embodiments in FIG. 7B to FIG. 7C.

It should be noted that, when the configuration rules of the same-color LED chips are followed, the first-color LED chip from any group, the second-color LED chip from any group, and the third-color LED chip from any group can be disposed in each pixel unit, and the first-color LED chip from any group, the second-color LED chip from any group, and the third-color LED chip from any group can be adjacent to each other. The relationship of the configuration of the first-color LED chip, the second-color LED chip, and the third-color LED chip can refer to the embodiments in FIG. 7A and FIG. 7D to FIG. 7E.

In summary, the LED chip binning configuration and the LED chip configuration method in the embodiments of the disclosure can reduce the color difference of the display module, and can increase the usage of the side bin to enhance the utilization rate of the LED chips. Moreover, the LED chip binning configuration and the LED chip configuration method in the embodiments of the disclosure can also reduce the binning time of the LED chips.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

What is claimed is:

1. An LED chip configuration method, comprising:
forming a plurality of LED chips from a wafer wherein the plurality of LED chips having the same color and different wavelengths;
binning the plurality of LED chips into a first group having a minimum wavelength range, a second group having a first middle wavelength range, and a third group having a maximum wavelength range wherein the minimum wavelength range, the first middle wavelength range, and the maximum wavelength range are not overlapped with each other;
providing a substrate; and
disposing LED chips from the first group, the second group, and the third group on the substrate;
wherein the disposed LED chips from different groups are arranged in a staggered manner.

2. The LED chip configuration method as claimed in claim 1, wherein the binning step further comprising binning the plurality of LED chips into groups according to a wavelength interval.

3. The LED chip configuration method as claimed in claim 1, wherein the wavelength ranges of the LED chips in the different groups are different.

4. The LED chip configuration method as claimed in claim 1, wherein the LED chip from the first group is not adjacent to the LED chip from the third group.

5. The LED chip configuration method as claimed in claim 1, wherein the LED chips from the same group are not adjacent to each other.

6. The LED chip configuration method as claimed in claim 1, wherein the binning step further comprising binning the plurality of LED chips into a fourth group having a second middle wavelength range, the LED chip from the second group is disposed adjacent to the LED chip from the fourth group.

7. The LED chip configuration method as claimed in claim 1, wherein the total wavelength range of the three groups is from 4 nm to 12 nm.

8. The LED chip configuration method as claimed in claim 1, wherein each of the LED chips is packaged by a transparent encapsulant.

9. The LED chip configuration method as claimed in claim 8, wherein the transparent encapsulant further includes a wavelength conversion material.

10. The LED chip configuration method as claimed in claim 1, where the plurality of LED chips are blue LED chips.
